(19) United States
(12) Patent Application Publication
(10) Pub. No.: US 2009/0045044 A1
(43) Pub. Date: Feb. 19, 2009

(54) Novel manufacturing design and processing methods and apparatus for sputtering targets

(76) Inventors: Jared Akins, Spokane, WA (US); Chi Tse Wu, Veradale, WA (US)

Correspondence Address: BUCHALTER NEMER, 18400 VON KARMAN AVE., SUITE 800, IRVINE, CA, 92612, US

(21) Appl. No.: 11/837,677

(22) Filed: Aug. 13, 2007

(51) Int. Cl. C23C 14/00; C23C 14/34

(52) U.S. Cl. 204/192.1; 204/298.03; 204/298.12

(57) ABSTRACT

Sputtering targets having a reduced burn-in time are described herein, where the target comprises an atmospheric plasma-treated surface material having at least about 10% reduced residual surface damage as compared to the residual surface damage of the surface material prior to atmospheric plasma treatment. Sputtering targets having reduced burn-in times are also described herein that include: a) an atmospheric plasma-finished surface material having an average grain size, and b) a core material having an average grain size, wherein the atmospheric plasma-finished surface material has an average surface roughness (Ra) equal to or less than about the average grain size of at least one of the surface material or the core material. An apparatus for producing sputtering targets having a reduced burn-in time, a reduced surface contamination or a combination of both has been developed that comprises an enclosure having a volume of air, an atmospheric plasma source positioned at least in part in the enclosure, a sputtering target positioned substantially inside the enclosure and at least one analytical instrument for measuring the constituent components in the volume of air, wherein at least part of the analytical instrument in located in the enclosure. Methods of producing sputtering targets having reduced burn-in times include: providing a surface material having at least some residual surface damage, providing an atmospheric plasmatron, forming an atmospheric plasma utilizing the atmospheric plasmatron, scanning at least part of the surface material with the atmospheric plasma in order to reduce the surface damage by at least about 10%.

### FIELD OF THE INVENTION

The field of the invention is manufacturing design and processing methods and apparatus for producing sputtering targets having a improved properties, such as a reduced burn-in time, improved surface cleanliness and, in some cases, improved surface microstructure.

### BACKGROUND

Electronic and semiconductor components are used in ever increasing numbers of consumer and commercial electronic products, communications products and data-exchange products. As the demand for consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the detects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, improved.

In addition to improving the quality of the layers of materials that are deposited or applied to surfaces, users also want to improve the length of time components, such as sputtering targets, can be used before their effective lifetime diminishes. In other words, users are looking to get the most out of stating materials, such as those found on a sputtering target, in order to decrease costs and maintenance time.

In a typical vapor deposition process, such as physical vapor deposition (PVD), a sample or target is bombarded with an energy source such as a plasma, laser or ion beam, until atoms are released into the surrounding atmosphere. The atoms that are released from the sputtering target travel towards the surface of a substrate (typically a silicon wafer) and coat the surface forming a thin film or layer of a material. Atoms are released from the sputtering target 10 and travel on an ion/atom path 30 towards the wafer or substrate 20, where they are deposited in a layer.

When a sputtering target is initially utilized, there is a period of time called the “burn-in time” where the surface of the target is “cleaned” of any contaminants or surface deformities in order to produce stable films on surfaces. This burn-in time is usually measured in kilowatt hours. Depending on the method of manufacturing and finishing the sputtering targets, burn-in time can be severely impacted because of surface imperfections and debris. One of the problems with a long burn-in time is that this extended time impacts productivity and overall cost of ownership of the sputtering targets.

U.S. Pat. No. 6,030,514 issued to Dunlop et al. addresses the extended burn-in time problem by utilizing non-mechanical methods to clean and polish the surface of targets before covering the target with a metal enclosure and optionally a passivating barrier layer. The metallic enclosure is designed to help reduce the burn-in time, along with the method of cleaning step. The metallic enclosure or metal layer is an additional step in the process, which can add cost and production time to the product.

US Patent Publication 2005/0040030 also discusses reducing the burn-in time of a target by dry treating the sputtering target using a sputtering ion plasma in a traditional magnetron/sputtering ion plasma arrangements and this publication reduces the burn-in time of the target in a vacuum chamber, as opposed to pretreating the surface material. The utilization of a vacuum chamber and magnetron/sputtering ion plasma arrangement can add costs, complexity and maintenance time to the production of the target. In addition, this publication does not discuss how a system can be constantly monitored during the sputtering stage in order to determine in “real time” when the target is ready for use.

To this ends it would be desirable to produce a sputtering target that fulfills at least one of the following goals: a) can be produced with a minimal amount of residual surface damage, b) can be produced to minimize burn-in times by at least 10% as compared to conventional sputtering targets, c) can be produced to minimize surface and near surface distortions of the crystallographic orientation, d) can be produced with a relatively clean target surface, e) can be produced efficiently without expensive vacuum chambers and magnetron sputtering ion plasma arrangements, and f) can be monitored in “real time” with standard analytical methods and/or instruments to determine when surface contaminant levels have been eliminated or reduced to acceptable levels.

### SUMMARY OF THE INVENTION

Sputtering targets having a reduced burn-in time are described herein, where the target comprises an atmospheric plasma-treated surface material having at least about 10% reduced residual surface damage as compared to the residual surface damage of the surface material prior to atmospheric plasma treatment.

Sputtering targets having reduced burn-in times are also described herein that include: a) an atmospheric plasma-finished surface material having an average grain size, and b) a core material having an average grain size, wherein the atmospheric plasma-finished surface material has an average surface roughness (Ra) equal to or less than about the average grain size of at least one of the surface material or the core material.

An apparatus for producing sputtering targets having a reduced burn-in time, a reduced surface contamination or a combination of both has been developed that comprises an enclosure having a volume of air, an atmospheric plasma source positioned at least in part in the enclosure, a sputtering target positioned substantially inside the enclosure and at least one analytical instrument for measuring the constituent components in the volume of air, wherein at least part of the analytical instrument in located in the enclosure.

Methods of producing sputtering targets having reduced burn-in times include: providing a surface material having at least some residual surface damage, providing an atmospheric plasmatron, forming an atmospheric plasma utilizing the atmospheric plasmatron, scanning at least part of the surface material with the atmospheric plasma in order to reduce the surface damage by at least about 10%.

### BRIEF DESCRIPTION OF THE FIGURES

FIG. 1 shows a contemplated apparatus 100 comprising a glove box 110 having a volume of air 120, an atmospheric plasma source 130 comprising a supporting post 134 and an atmospheric plasmatron 137, a sputtering target 140 positioned on top of a turn table 150, and a residual etched species analyzer 170 for measuring the constituent components in the volume of air, wherein the residual etched species collecting conduit 160 that is connected to the residual species analyzer 170 is in located in the enclosure.

FIG. 2 shows the arrangement of a plasma-treatment process in action. The chamber 210 contains a volume of air 220. A gas feed 232 is introduced into the chamber 210. A plasma 235 is ignited and focused on a substrate or target surface 240. The analytical instrument is not shown in this embodiment.

FIG. 3, another contemplated arrangement of the apparatus 300 for producing sputtering targets having a reduced burn-in time, a reduced surface contamination or a combination of both is shown.

### DESCRIPTION OF THE SUBJECT MATTER

A sputtering target has been produced that meets at least one of the following goals: a) can be produced with a minimal amount of residual surface damage, b) can be produced to minimize burn-in times by at least 10% as compared to conventional sputtering targets, c) can be produced to minimize surface and near surface distortions of the crystallographic orientation, d) can be produced with a relatively clean target surface, e) can be produced efficiently without expensive vacuum chambers and magnetron sputtering ion plasma arrangements, and f) can be monitored in “real time” with standard analytical methods and/or instruments to determine when surface contaminant levels have been eliminated or reduced to acceptable levels.

In addition, methods and apparatus have been discovered that can successfully identify the thickness of the surface layer and the degree of residual surface damage and in turn help to understand the impact of this residual surface damage on the burn-in time of the target. The target materials and methods described herein accomplish many of the same goals as U.S. Ser. No. 11/595,658 filed on Nov. 9, 2006, which is commonly-owned by Honeywell International Inc. and incorporated herein in its entirety by reference. Specifically, an apparatus for producing sputtering targets having a reduced burn-in time, a reduced surface contamination or a combination of both has been developed that comprises an enclosure having a volume of air, an atmospheric plasma source positioned at least in part in the enclosure, a sputtering target positioned substantially inside the enclosure and at least one analytical instrument for measuring the constituent components in the volume of air, wherein at least part of the analytical instrument in located in the enclosure.

One key difference between the subject matter disclosed herein and the application mentioned above is that the surface materials are processed and improved herein through the use of an atmospheric plasma. In addition, and what may possibly be a more important aspect, is the use of analytical methods and instrumentation, such as a spectrometer. These instruments and methods are used to collect the removed species, analyze them and determine what those species are. From this analysis, one can determine if the part is clean.

Sputtering targets having a reduced burn-in time are described herein, where the target comprises an atmospheric plasma-treated surface material having at least about 10% reduced residual surface damage as compared to the residual surface damage of the surface material prior to atmospheric plasma treatment. In addition, sputtering targets having reduced burn-in times are described herein that include: a) an atmospheric plasma-finished surface material having an average grain size, and b) a core material having an average grain size, wherein the atmospheric plasma-finished surface material has an average surface roughness (Ra) equal to or less than about the average grain size of at least one of the surface material or the core material.

Sputtering targets are also contemplated that have a reduced burn-in time, comprising an atmospheric plasma-treated surface material having at least about 10% reduced residual surface damage as compared to the surface damage of the original surface material. In some embodiments, the atmospheric plasma-treated surface material has at least about 25% reduced residual surface damage as compared to the surface damage of the original surface material. In other embodiments, the atmospheric plasma-treated surface material has at least about 40% reduced residual surface damage as compared to the surface damage of the original surface material. In yet other embodiments, the atmospheric plasma-treated surface material has at least about 75% reduced residual surface damage as compared to the surface damage of the original surface material.

As mentioned in the background, more powerful, complex and expensive plasma treatments have been traditionally utilized to treat sputtering target surfaces. Some of the benefits of the methods utilized herein that incorporate atmospheric plasma surface treatment are: a) targets can be cleaned with or without chemicals, b) targets can be cleaned controllably through the use of an optical sensor, c) atmospheric plasmas can work in conjunction with other plasma and high temperature treatment processes to anneal the microstructure of the surface material, d) as mentioned, there's a noticeable and quantifiable reduction in the burn-in time for the surface material, and e) the treated surface material experiences less arcing during normal use, as compared to a non-treated surface material.

Atmospheric plasmas are an important improvement to the processing of target materials, because these plasmas are low temperature and easily utilized without expensive and complicated vacuum and ion chambers. These plasmas have traditionally been utilized to pre-treat fabrics and woven substrates, in addition to pretreating polymer and polymer-based substrates to accept metal deposition. Plasmas of this kind have also been used to break down volatile organic compositions in air. (see Poteat, Sandra L., “Control of Volatile Organic Compounds With a Pulsed Corona Discharge”, North Carolina State University Dissertation, 2001) They have not been used, however, to pre-treat sputtering target surfaces.

Sputtering targets and sputtering target assemblies contemplated and produced herein comprise any suitable shape and size depending on the application and instrumentation used in the vapor deposition processes. Sputtering targets contemplated and produced herein comprise a surface material having an average grain size and a core material (which includes the backing plate) having an average grain size. The surface material and core material may generally comprise the same elemental makeup or chemical composition/component, or the elemental makeup and chemical composition of the surface material may be altered or modified to be different than that of the core material. However, in embodiments where it may be important to detect when the target's useful life has ended or where it is important to deposit a mixed layer of materials, the surface material and the core material may be tailored to comprise a different elemental makeup or chemical composition.

The surface material is that portion of the target that is intended to produce atoms and/or molecules that are deposited via vapor deposition to form the surface coating/thin film. This surface material is important because it is this layer of material that directly affects burn-in time, as discussed earlier. Conventional sputtering targets are generally manufactured and finished by sanding or buffing the surface material, and while this process produces a uniform and attractive surface appearance, the process leaves behind a relatively significant amount of residual surface damage and surface particulate/debris. In contemplated embodiments, as discussed herein, sputtering targets are instead atmospheric plasma-finished in order to produce a surface material with a lower incidence of residual surface damage. In other embodiments, sputtering targets are atmospheric plasma-finished to produce a surface material with quantitatively little to no residual surface damage.

The phrase “residual surface damage” as used herein refers to that portion of a sputtering target that does not contain material or material configurations that are suitable for desirable sputtered layers. For example, in some embodiments, residual surface damage may be the presence of layers or pockets of crystal grains that are “misoriented” or not oriented in such as fashion as to properly direct sputtered atoms. There may be surface or near surface distortion of the crystallographic lattice. In other embodiments, residual surface damage may be the presence of layers or pockets of debris, particulate or other materials that are not considered to be suitable sputterable material, such as sand, dust, grit or other materials. In yet other embodiments, residual surface damage may be the presence of layers or pockets of uneven terrain on the sputtering target. This embodiment is different from misoriented crystal grains, in that there are portions of the sputtering target itself that are damaged beyond just misoriented crystal grains, and this damage is more significant than misoriented crystal grains. In other embodiments, residual surface damage refers to a combination of two or more of the above. It should be obvious, however, that the degree of residual surface damage can directly impact the burn-in time of the target or the time it takes before the target becomes useful for sputtering acceptable layers of materials on a surface.

As mentioned, it has been discovered that surface roughness is a component of residual surface damage and has a direct correlation to the burn-in times for a sputtering target. Therefore, it is important to ensure that the surface roughness is minimized for all types of targets. Some targets, such as tantalum, present problems when trying to minimize surface roughness. A conventional sanding or buffing process is used to remove surface roughness, and while it is successful in producing a uniform product, it leaves particulate or debris deposition on the target—another contributor to residual surface damage and slow burn-in times. Therefore, in contemplated embodiments, the surface material is atmospheric plasma-finished—meaning that the surface is treated for a sufficient time with an atmospheric plasma without leaving behind deposits, particulates or debris. In some embodiments, the atmospheric plasma may be used to clean the surface material by utilizing argon, for example, and in other embodiments, the atmospheric plasma may be used to anneal the surface by utilizing helium, for example.

In contemplated embodiments, as mentioned, average surface roughness (Ra) should be equal to or lower than about the average grain size of the bulk material. In some embodiments, contemplated atmospheric plasma-finished surface materials comprise less than about 64 microinches surface roughness (Ra). In other embodiments, contemplated surface materials comprise less than about 32 microinches surface roughness (Ra). In yet other embodiments, contemplated surface materials comprise less than about 16 microinches surface roughness (Ra).

In addition, contemplated sputtering targets may be annealed to further reduce any residual surface damage by utilizing atmospheric plasma treatment. Surface stresses may also be removed by utilizing a thermal treatment, such as laser treatment, e-beam treatment, thermal treatment or plasma spray treatment, heat contact treatment, etc. When utilizing both at least one annealing step and at least one thermal treatment step, the goal is to anneal out the residual surface damage and create a recrystallized layer that is defect free. Examples of thermal treatments include e-beam, laser treatment, thermal spray, plasma spray, explosive flash treatments, etc.

Sputtering targets contemplated herein may generally comprise any material that can be a) reliably formed into a sputtering target; b) sputtered from the target when bombarded by an energy source; and c) suitable for forming a final or precursor layer on a water or surface. Materials that are contemplated to make suitable sputtering targets are metals, metal alloys, conductive polymers, conductive composite materials, dielectric materials, hardmask materials and any other suitable sputtering material. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Contemplated metals include titanium, silicon, cobalt, copper, nickel, iron, zinc, vanadium, zirconium, aluminum and aluminum-based materials, tantalum, niobium, tin, chromium, platinum, palladium, gold, silver, tungsten, molybdenum, cerium, promethium, ruthenium or a combination thereof. In some embodiments, contemplated metals include copper, aluminum, tungsten, titanium, cobalt, tantalum, magnesium, lithium, silicon, manganese, iron or a combination thereof. Most preferred metals include copper, aluminum and aluminum-based materials, tungsten, titanium, zirconium, cobalt, tantalum, niobium, ruthenium or a combination thereof. Specific examples of contemplated materials, include aluminum and copper for superfine grained aluminum and copper sputtering targets; aluminum, copper, cobalt, tantalum, zirconium, and titanium for use in 200 mm and 300 mm sputtering targets, along with other mm-sized targets; and aluminum for use in aluminum sputtering targets that deposit a thin, high conformal “seed” layer or “blanket” layer of aluminum surface layers. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

The term “metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, ruthenium, tantalum, tin, zinc, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafnium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel vanadium, tungsten titanium, tantalum ruthenium, copper manganese, germanium antimony telluride, copper gallium, indium selenide, copper indium selenide and copper indium gallium selenide and/or combinations thereof.

As far as other materials that are contemplated herein for sputtering targets, the following combinations are considered examples of contemplated sputtering targets (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof. In some embodiments, contemplated materials include those materials disclosed in U.S. Pat. No. 6,331,233, which is commonly-owned by Honeywell International Inc., and which is incorporated herein in its entirety by reference.

Methods of producing sputtering targets having reduced burn-in times include: providing a surface material having at least some residual surface damage, providing an atmospheric plasmatron, forming an atmospheric plasma utilizing the atmospheric plasmatron, scanning at least part of the surface material with the atmospheric plasma in order to reduce the surface damage by at least about 10%. In this method, it should be clear that either the target is produced with a surface material that blends in with the core material to produce a target, or the target is produced with a surface material that is coupled to the core material to produce a target.

In determining the residual surface damage, methods have been developed that include: providing a sputtering target having a surface, wherein the surface comprises a plurality of surface damage constituents, providing an electron beam, scanning the surface with the electron beam, collecting data from the electron beam scanning, wherein the data provides a local variation in surface damage constituents; and utilizing the data to determine the thickness of the surface layer and the degree of residual surface damage.

One of the techniques utilized in contemplated methods of determining residual surface damage is Electron Backscatter Diffraction (EBSD), which is a technique which allows crystallographic and surface damage constituent information to be obtained from samples in the scanning electron microscope (SEM). In EBSD, a stationary electron beam strikes a tilted sample and the diffracted electrons form a pattern on a fluorescent screen. This pattern is characteristic of the crystal structure and orientation of the sample region from which it was generated. The diffraction pattern can be used to measure the crystal orientation and surface damage constituents, measure grain boundary misorientations, discriminate between different materials, and provide information about local crystalline perfection and surface damage constituents. When the beam is scanned in a grid across a polycrystalline sample and the crystal orientation measured at each point, the resulting map will reveal the constituent grain morphology, orientations, and boundaries. This data can also be used to show the preferred crystal orientations (texture) present in the material. A complete and quantitative representation of the sample microstructure can be established with EBSD. (see HTTP://WWW.EBSD.COM/EBSDEXPLAINED.HTM)

One can measure crystal imperfection and surface damage constituents with various X-ray techniques, however, these techniques are neither straight forward to implement nor to interpret. Additionally, with X-ray a majority of the information comes from a very thin surface layer. The signal decays exponentially with depth. In the case of Ta and the most common Cu K-alpha radiation, 95% of the signal comes from a depth of less than 5 micron. In addition to that, the information gathered by X-ray diffraction is of a macroscopic nature. It is averaged over all the grains illuminated by the beam. With EBSD, one gets grain by grain information of the state of local misorientation. If the crystal imperfections and surface damage constituents are localized, such as under the machining grooves, it would affect sputtering and it would show up with the EBSD technique.

Methods utilizing atmospheric plasma treatment, as described herein, may also be used to not only remove residual surface damage from the surface material, but may also be utilized to clean the sidewalls, sputter trap, flange and any other parts of the target assembly. In addition, these methods may be used to clean the bond surface of the surface material, so that it may be cleanly applied to the core material, which includes the backing plate.

In order to determine if the surface material and other desirable surfaces have been sufficiently cleaned and/or annealed, the product gases may be analyzed to determine their content and whether the gases contain undesirable products that are still being removed from the surfaces or contain volatilized surface materials, which would indicate that the surface is sufficiently clean and/or annealed. As mentioned, an apparatus for producing sputtering targets having a reduced burn-in time, a reduced surface contamination or a combination of both has been developed that comprises an enclosure having a volume of air, an atmospheric plasma source positioned at least in part in the enclosure, a sputtering target positioned substantially inside the enclosure and at least one analytical instrument for measuring the constituent components in the volume of air, wherein at least part of the analytical instrument in located in the enclosure.

As contemplated herein, an enclosure having a volume of air may be any suitable enclosure that can house an atmospheric plasma source and plasma and at least part of a sputtering target. In some embodiments, the enclosure will be designed to withstand vacuum pressures and related plasmas. As mentioned, at least one analytical instrument for measuring the constituent components in the volume of air is also contemplated, wherein at least part of the analytical instrument is located in the enclosure. For example, an analytical instrument having a probe assembly may be located outside of the enclosure and the probe may be located inside the enclosure where it can send information back to the instrument. In another contemplated embodiment, the entire analytical instrument may be located inside the enclosure. In yet another contemplated embodiment, the analytical instrument may be located inside the enclosure but connected to a data line that is connected to a computer or media storage site.

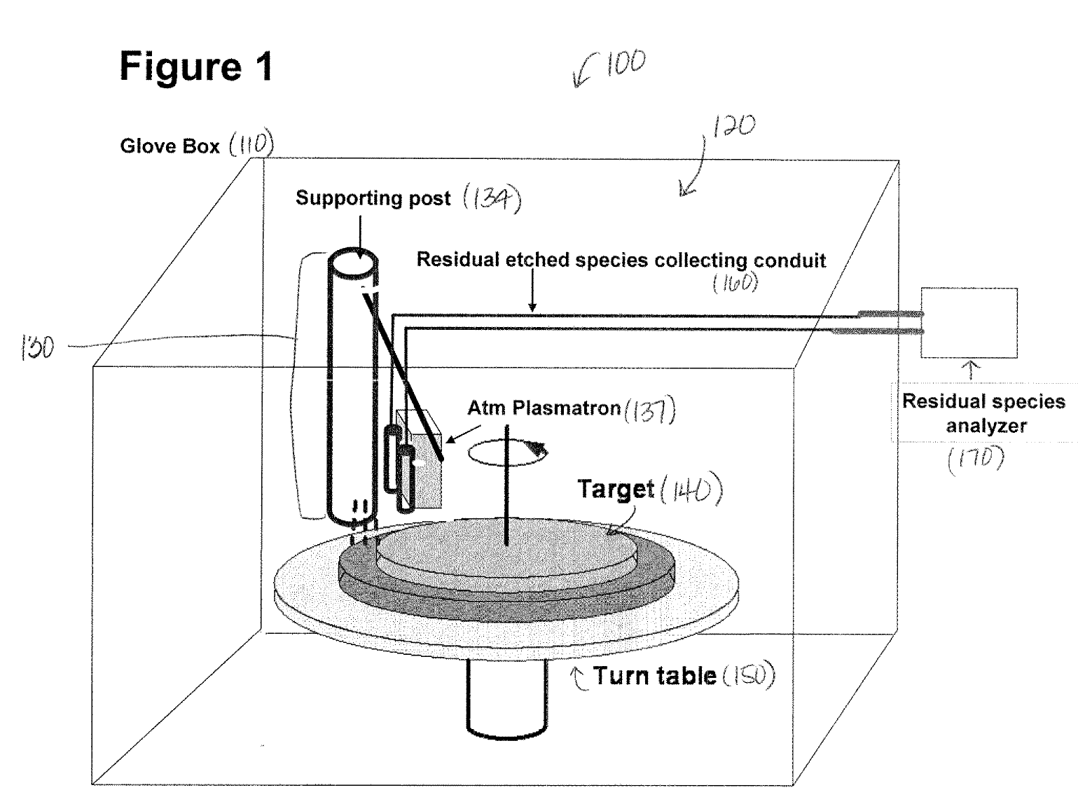

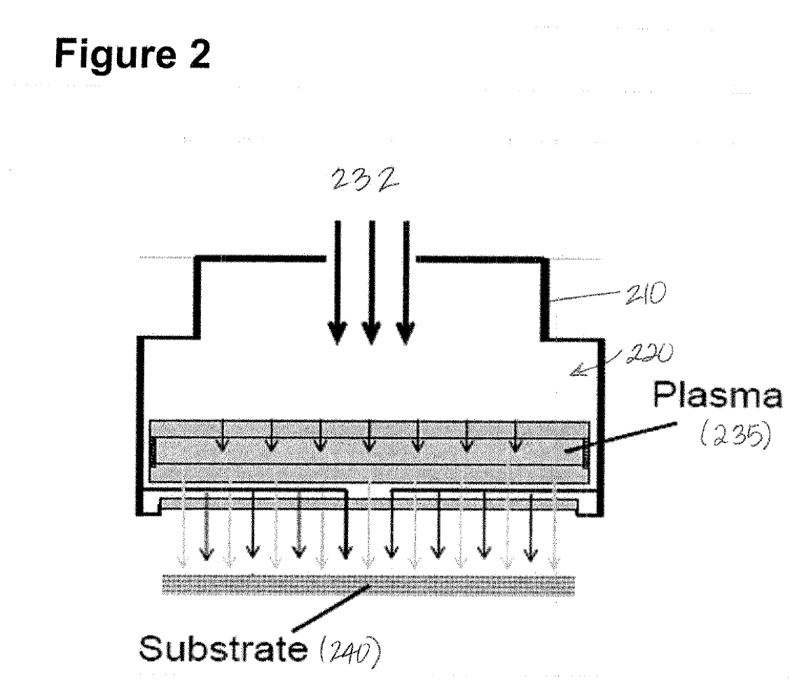

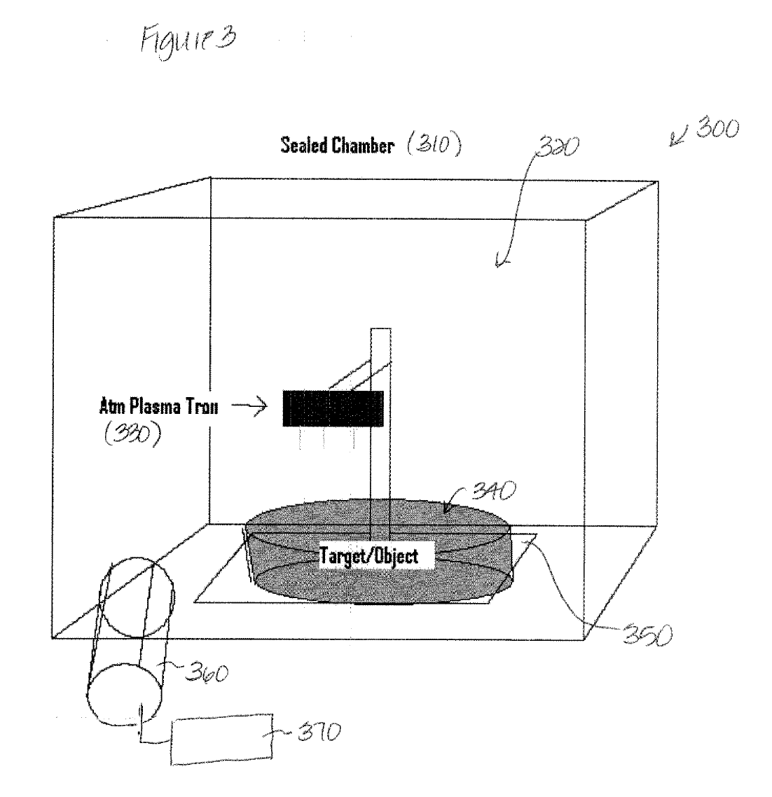

In some embodiments, there are at least two apparatus that may be used to effect atmospheric plasma-treatment of the surface materials, such as the one shown in FIG. 1, FIG. 2 or FIG. 3. FIG. 1 shows a contemplated apparatus 100 comprising a glove box 110 having a volume of air 120, an atmospheric plasma source 130 comprising a supporting post 134 and an atmospheric plasmatron 137, a sputtering target 140 positioned on top of a turn table 150, and a residual etched species analyzer 170 for measuring the constituent components in the volume of air, wherein the residual etched species collecting conduit 160 that is connected to the residual species analyzer 170 is in located in the enclosure. FIG. 2 shows the arrangement of a plasma-treatment process in action. The chamber 210 contains a volume of air 220. A gas feed 232 is introduced into the chamber 210. A plasma 235 is ignited and focused on a substrate or target surface 240. The analytical instrument is not shown in this embodiment. In FIG. 3, another contemplated arrangement of the apparatus 300 for producing sputtering targets having a reduced burn-in time, a reduced surface contamination or a combination of both is shown. This contemplated apparatus 300 comprising a sealed chamber 310 having a volume of air 320, an atmospheric plasma source 330 comprising a supporting post 334 and an atmospheric plasmatron 337, a sputtering target/object 340 positioned on top of a platform 350, and a residual gas analyzer 370 for measuring the constituent components in the volume of air, wherein the vacuum port 360 that is connected to the residual gas analyzer 370 is in located in the enclosure.

One contemplated apparatus may comprise an atmospheric plasmatron, the object to clean and/or anneal, a suitable container for the process, and various automation components, which are designed to control the process through automation. In another contemplated embodiment, an apparatus may additionally and optionally include a residual gas analyzer (RGA) or optical sensor and a vacuum system pump. Various iterations of these components may be utilized depending on the type of atmospheric plasma treatment desired.

As should be clear from this disclosure, the use of atmospheric plasma treatment for surface materials of sputtering target assemblies is not only novel, but effective for the purpose of cleaning, annealing and/or reducing burn-in time, especially when coupled with the use of analytical instrumentation to measure the volume of air in the enclosure or chamber.

### EXAMPLES

The plasma conditions include using hydrogen as the plasma gas, 100W of power, a part temperature of about 200° C., a distance between the plasma head and the part of about 3 mm, a scan speed of about 2.5 mm/s, and 6 sweeps of the part. Oxygen was also used with the same settings explained above, with the temperature at room temperature and at 200 C. A combination of the two cleans was also utilized in which the part was cleaned with the H2 plasma first and followed by the oxygen plasma.

Thus, specific embodiments and applications of methods of manufacturing sputtering targets and related apparatus have been disclosed. It should be apparent, however, to those skilled in the art that many more modifications besides those already described are possible without departing from the inventive concepts herein. The inventive subject matter, therefore, is not to be restricted except in the spirit of the disclosure and claims herein. Moreover, in interpreting the disclosure and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A sputtering target having a reduced burn-in time, the target comprising an atmospheric plasma-treated surface material having at least about 10% reduced surface damage as compared to the surface damage of the surface material prior to atmospheric plasma treatment.

2. The sputtering target of claim 1, wherein the surface damage is reduced by at least about 25%.

3. The sputtering target of claim 2, wherein the surface damage is reduced by at least about 50%.

4. The sputtering target of claim 3, wherein the surface damage is reduced by at least about 75%.

5. A sputtering target having reduced burn-in times, comprising:
an atmospheric plasma-finished surface material having an average grain size, and
a core material having an average grain size, wherein the atmospheric plasma-finished surface material has an average surface roughness (Ra) equal to or less than about the average grain size of at least one of the surface material or the core material.

6. The sputtering target of claim 5, wherein the burn-in time is reduced by at least 50% over a conventional sputtering target comprising a non-atmospheric plasma-finished surface material.

7. The sputtering target of claim 6, wherein the burn-in time is reduced by at least 75% over a conventional sputtering target comprising a non-atmospheric plasma-finished surface material.

8. The sputtering target of one of claims 1 or 5, wherein the surface material comprises at least one refractory metal.

9. The sputtering target of one of claims 1 or 5, wherein the at least one refractory metal comprises tantalum, titanium, tungsten, molybdenum, cobalt, nickel or combinations thereof.

10. The sputtering target of claim 5, wherein the surface material and the core material comprise the same materials.

11. An apparatus for producing sputtering targets having a reduced burn-in time, a reduced surface contamination or a combination of both, comprising:
an enclosure having a volume of air,
an atmospheric plasma source positioned at least in part in the enclosure,
a sputtering target positioned substantially inside the enclosure, and
at least one analytical instrument for measuring the constituent components in the volume of air, wherein at least part of the analytical instrument in located in the enclosure.

12. The apparatus of claim 11, wherein the at least one analytical instrument comprises a residual gas analyzer, residual species analyzer or a combination thereof.

13. A method of producing a sputtering target having reduced burn-in times, comprising:
providing a surface material having at least some residual surface damage,
providing an atmospheric plasmatron,
forming an atmospheric plasma utilizing the atmospheric plasmatron, and
scanning at least part of the surface material with the atmospheric plasma in order to reduce the surface damage by at least about 10%.

14. The method of claim 13, further comprising annealing the surface material to reduce the residual surface damage.

15. The method claim 13, further comprising annealing the surface material to reduce the residual surface damage and thermally treating the surface material to recrystallize the surface material.

16. The method of claim 13, wherein the burn-in time is reduced by at least 50% over a conventional sputtering target comprising a non-atmospheric to plasma-finished surface material.

17. The method of claim 13, wherein the surface material comprises at least one refractory metal.

18. The method of claim 17, wherein the at least one refractory metal comprises tantalum, titanium, tungsten, molybdenum, cobalt, nickel or combinations thereof.

19. The method of claim 13, wherein the burn-in time is reduced by at least 50% over a conventional sputtering target comprising a non-atmospheric plasma-finished surface material.

20. The method of claim 13, wherein the burn-in time is reduced by at least 75% over a conventional sputtering target comprising a non-atmospheric plasma-finished surface material.
